(19) United States
(12) Patent Application Publication
(10) Pub. No.: US 2026/0190672 A1
(43) Pub. Date: Jul. 2, 2026

(54) DISPLAY DEVICE

(71) Applicant: LG Display Co., Ltd., Seoul (KR)

(72) Inventors: JinWoo HONG, Seoul (KR); Doeon PARK, Gumi-si (KR); Yong-Ku LEE, Gimpo-si (KR); Jaebin SONG, Seoul (KR)

(73) Assignee: LG Display Co., Ltd., Seoul (KR)

(21) Appl. No.: 19/424,944

(22) Filed: Dec. 18, 2025

(30) Foreign Application Priority Data
Dec. 30, 2024 (KR) 10-2024-0200971

(51) Int. Cl. H10K 59/124; H10K 59/122

(52) U.S. Cl. CPC H10K 59/124; H10K 59/122

(57) ABSTRACT

A display device includes a substrate, a planarization layer disposed on the substrate and including a groove, a light emitting diode disposed on the planarization layer, the light emitting diode including a first electrode overlapping the groove, an emission layer disposed on the first electrode, and a second electrode disposed on the emission layer and an optical member having a bar shape disposed on the light emitting diode. The emission layer includes a first portion disposed at a center and a second portion enclosing the first portion and disposed at an edge, and a thickness of the second portion is greater than a thickness of the first portion. Accordingly, luminance deviation according to a viewing angle may be minimized.

### CROSS-REFERENCE TO RELATED APPLICATIONS

This application claims the benefit of and priority to Korean Patent Application No. 10-2024-0200971 filed on Dec. 30, 2024, in the Korean Intellectual Property Office, the entire contents of which are incorporated herein by reference for all purposes.

### BACKGROUND

### 1. Technical Field

The present disclosure relates to a display device, and particularly to, for example, without limitation, a display device that minimizes luminance deviation depending on a viewing angle.

### 2. Description of Related Art

As technology advances in modern society, display devices are variously utilized to provide information to users. Display devices are included not only in electric signboards that simply transmit visual information in one direction, but also in various electronic devices that require higher technology to recognize user input and provide information in response to the recognized input.

For example, a display device may be included in a vehicle to provide various information to the driver and passengers of the vehicle. However, the display device of the vehicle needs to appropriately display content so as not to interfere with the operation of the vehicle. For instance, the display device may need to restrict the display of content that may reduce driving concentration while the vehicle is in operation.

The description of related art should not be considered prior art merely because it is mentioned in or associated with this section. The description of related art includes information that describes one or more aspects of the subject technology, and the description in this section does not limit the scope of the present disclosure.

### SUMMARY

An aspect of the present disclosure is to provide a display device capable of controlling a viewing angle.

An aspect of the present disclosure is to provide a display device in which luminance deviation according to a viewing angle is improved.

An aspect of the present disclosure is to provide a display device that minimizes luminance deviation according to a viewing angle, which may occur between degraded areas and non-degraded areas among emission areas.

An aspect of the present disclosure is to provide a display device with improved display quality by implementing uniform luminance.

An aspect of the present disclosure is to provide a display device that minimizes the influence of pixel shrinkage caused by out-gassing.

Aspects of the present disclosure are not limited to the above-mentioned aspects, and other aspects, which are not mentioned above, can be clearly understood by those skilled in the art from the following descriptions.

A display device according to an example embodiment of the present disclosure includes a substrate, a planarization layer disposed on the substrate and including a groove, a light emitting diode disposed on the planarization layer, the light emitting diode including a first electrode overlapping the groove, an emission layer disposed on the first electrode, and a second electrode disposed on the emission layer, and an optical member having a bar shape disposed on the light emitting diode. The emission layer includes a first portion disposed at a center and a second portion enclosing the first portion and disposed at an edge, and a thickness of the second portion is greater than a thickness of the first portion.

A display device according to another example embodiment of the present disclosure includes a substrate, an active area in which a plurality of sub pixels is defined, a non-active area outside the active area, a planarization layer disposed on the substrate, a first light emitting diode and a second light emitting diode disposed in each of the plurality of sub pixels, a first optical member disposed on the first light emitting diode and having a semi-cylindrical shape and a second optical member disposed on the second light emitting diode and having a hemispherical shape. Each of the first light emitting diode and the second light emitting diode includes a first electrode, an emission layer, and a second electrode. The emission layer includes a first portion disposed at a center and a second portion enclosing the first portion and disposed at an edge. A thickness of the second portion of the emission layer of the first light emitting diode is greater than a thickness of the first portion of the emission layer of the first light emitting diode. A thickness of the second portion of the emission layer of the second light emitting diode is the same as a thickness of the first portion of the emission layer of the second light emitting diode. Accordingly, luminance deviation according to a viewing angle may be minimized.

Other detailed matters of the example embodiments are included in the detailed description and the drawings.

According to one or more aspects of the present disclosure, luminance deviation according to a viewing angle, which may occur between degraded emission areas and non-degraded emission areas, may be reduced.

According to one or more aspects of the present disclosure, display quality may be improved by implementing uniform luminance.

According to one or more aspects of the present disclosure, the influence of pixel shrinkage caused by out-gassing may be minimized.

The effects According to one or more aspects of the present disclosure are not limited to the contents described above, and more various effects are included in the present specification.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is an example diagram of a display device according to an example embodiment of the present disclosure;

FIG. 2 is a functional block diagram of a display device according to an example embodiment of the present disclosure;

FIG. 3 is an enlarged plan view of a pixel of a display device according to an example embodiment of the present disclosure;

FIG. 4 is a cross-sectional view taken along IV-IV′ of FIG. 3;

FIG. 5 is a cross-sectional view taken along V-V′ of FIG. 3; and

FIG. 6 is a cross-sectional view of a pixel of a display device according to another example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including”, “having”, and “consist of” used herein are generally intended to allow other components to be added unless the terms are used with the term “only”. Any references to singular may include plural unless expressly stated otherwise. In one or more examples, unless expressly stated otherwise, an element may be one or more elements; and an element may include a plurality of elements.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used to refer to one element separately from another. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

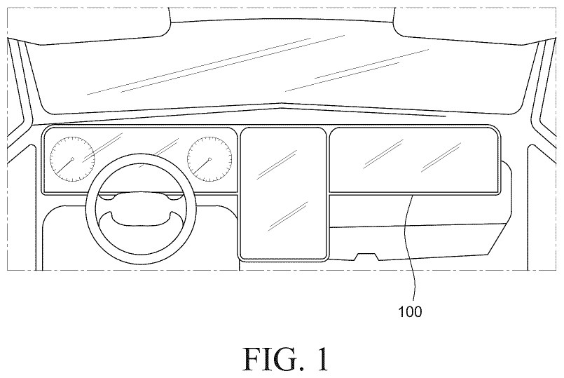

FIG. 1 is an example diagram of a display device according to an example embodiment of the present disclosure.

Referring to FIG. 1, a display device 100 may be disposed on at least a part of a dashboard of a vehicle. The dashboard of the vehicle may include a configuration disposed in front of the front seats (e.g., driver's seat, passenger's seat) of the vehicle. For example, the dashboard of the vehicle may include an input configuration disposed to operate various functions inside the vehicle (e.g., air conditioner, audio system, navigation system).

The display device 100 may be disposed on the dashboard of the vehicle and may operate as an input unit for controlling at least some of the various functions of the vehicle. The display device 100 may provide various information related to the vehicle, for example, driving information of the vehicle (e.g., current speed of the vehicle, remaining fuel amount, driving distance), or information regarding parts of the vehicle (e.g., damage level of the vehicle tires).

The display device 100 may be disposed so as to extend across the driver's seat and the passenger's seat disposed in front of the vehicle. A user of the display device 100 may include the driver of the vehicle and a passenger seated in the passenger's seat. Both the driver and the passenger may use the display device 100.

The display device 100 illustrated in FIG. 1 may represent only a part thereof. The display device 100 illustrated in FIG. 1 may represent a display panel among various configurations included in the display device 100. Specifically, for example, the display device 100 illustrated in FIG. 1 may represent at least a part of an active area and a non-active area of the display panel. Configurations other than the part of the display device 100 illustrated in FIG. 1 may be mounted inside (or at least partially) the vehicle.

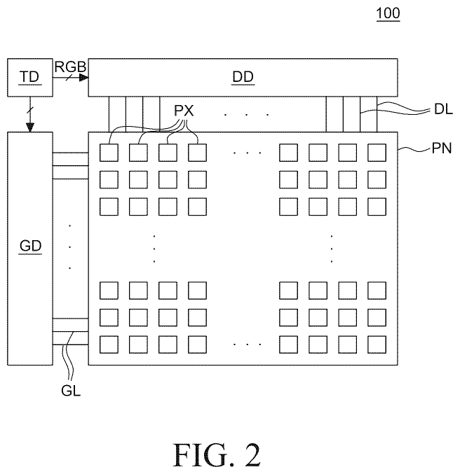

FIG. 2 is a functional block diagram of the display device according to an example embodiment of the present disclosure.

The display device according to an example embodiment of the present disclosure may apply an electroluminescent display device. The electroluminescent display device may be implemented as an organic light emitting diode display device, a quantum-dot light emitting diode display device, or an inorganic light emitting diode display device.

Referring to FIG. 2, the display device 100 may include a display panel PN, a data driving circuit DD, a gate driving circuit GD, and a timing controller TD.

The display panel PN may generate images to be provided to a user. For example, the display panel PN may generate and display images to be provided to the user through a plurality of pixels PX in which pixel circuits are respectively disposed.

The data driving circuit DD, the gate driving circuit GD, and the timing controller TD may provide signals for operating each pixel PX through signal lines. For example, the signal lines for providing the signals for operating each pixel PX may include a plurality of data lines DL and a plurality of gate lines GL.

The plurality of data lines DL may be disposed in a column direction and may include a plurality of wiring lines connected to pixels PX disposed in one column direction, and the plurality of gate lines GL may be disposed in a row direction and may include a plurality of wiring lines connected to pixels PX disposed in one row direction.

In some cases, the display device 100 may further include a power supply unit. In this case, signals for operating pixels PX may be provided through a power supply line connecting the power supply unit and the display panel PN. Depending on the example embodiment, the power supply unit may provide power to the data driving circuit DD and the gate driving circuit GD. The data driving circuit DD and the gate driving circuit GD may be driven based on the power provided from the power supply unit.

For example, the data driving circuit DD may apply data signals to each pixel PX through the plurality of data lines DL, the gate driving circuit GD may apply gate signals to each pixel PX through the plurality of gate lines GL, and the power supply unit may supply a power voltage to each pixel PX through a power voltage supply line.

The timing controller TD may control the data driving circuit DD and gate driving circuit GD. For example, the timing controller TD may rearrange digital video data RGB input from the outside according to the resolution of the display panel PN and supply it to the data driving circuit DD.

The data driving circuit DD may convert the digital video data input from timing controller TD into an analog data voltage based on a data control signal, and may supply the analog data voltage to the plurality of data lines DL.

The gate driving circuit GD may generate a scan signal and a light emitting signal based on a gate control signal. For example, the gate driving circuit GD may include a scan driver and a light emitting signal driver. The scan driver may generate scan signals in a row-sequential manner to drive at least one scan line connected to each pixel row, and may supply the scan signals to the scan lines. The light emitting signal driver may generate light emitting signals in a row-sequential manner to drive at least one light emitting signal line connected to each pixel row, and may supply the light emitting signals to the light emitting signal lines.

Depending on the example embodiment, the gate driving circuit GD may be disposed on the display panel PN in a gate-driver in panel (GIP) method. For example, the gate driving circuit GD may be divided into a plurality of units and may be disposed on at least two sides of the display panel PN, respectively.

The display panel PN may include an active area and a non-active area enclosing the active area.

The active area of the display panel PN may include a plurality of pixels PX disposed in a row direction and a column direction. For example, the plurality of pixels PX may be disposed in an area where the plurality of data lines DL and the plurality of gate lines GL intersect.

One pixel PX may include a plurality of sub pixels emitting different colors. For example, one pixel PX may implement blue, red, and green colors using three sub pixels. However, the present disclosure is not limited thereto, and in some cases, the pixel PX may further include a sub pixel for further implementing a specific color, for example, white.

In the pixel PX, an area implementing blue may be referred to as a blue sub pixel, an area implementing red may be referred to as a red sub pixel, and an area implementing green may be referred to as a green sub pixel.

Each of the plurality of sub pixels may include a first light emitting diode and a second light emitting diode that emit the same color.

Each of the plurality of sub pixels may include a first optical member refracting light from the first light emitting diode in a specific direction and a second optical member refracting light from the second light emitting diode in a specific direction. For example, the first optical member and the second optical member may be implemented as lenses, but the example embodiments of the present disclosure are not limited thereto.

For example, the first optical member may be disposed in an optical area that provides light to a first range to form a first viewing angle, and the second optical member may be disposed in an optical area that provides light to a second range to form a second viewing angle. The second range may correspond to a wider range than the first range. Accordingly, the first optical member and the second optical member may suppress the viewing angle of each of the plurality of sub pixels.

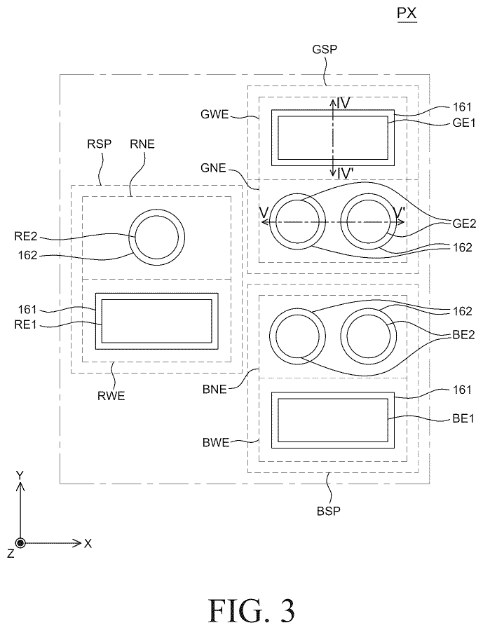

A detailed description of the first optical member and the second optical member will be given hereinafter with reference to FIGS. 3 to 5.

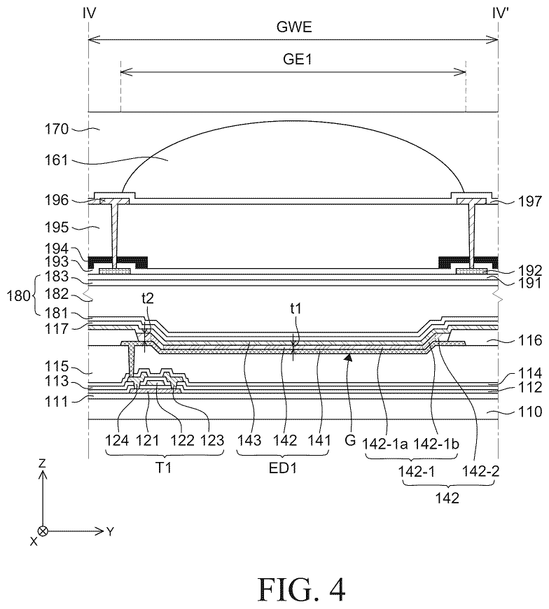

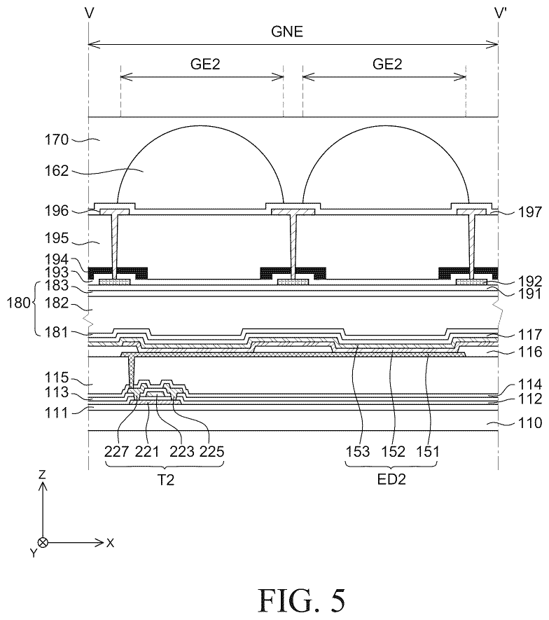

FIG. 3 is an enlarged plan view of a pixel of the display device according to an example embodiment of the present disclosure. FIG. 4 is a cross-sectional view taken along line IV-IV′ of FIG. 3. FIG. 5 is a cross-sectional view taken along line V-V′ of FIG. 3.

Meanwhile, FIG. 3 illustrates a plan view of pixel PX in a case where the pixel PX includes three sub pixels, for example, a first sub pixel RSP, a second sub pixel GSP, and a third sub pixel BSP.

In addition, FIG. 4 illustrates a sub pixel in which a first optical member 161 is disposed, as an example embodiment of the display device 100 cut along line IV-IV′ of FIG. 3, and FIG. 5 illustrates a sub pixel in which a second optical member 162 is disposed, as an example embodiment of the display device 100 cut along line V-V′ of FIG. 3.

Meanwhile, in FIGS. 4 and 5, for convenience of explanation, only an area corresponding to the first optical area GWE and the second optical area GNE of the second sub pixel GSP among the three sub pixels RSP, GSP, and BSP illustrated in FIG. 3 is illustrated, but other sub pixels RSP and BSP may also be formed with the same configuration.

For convenience of explanation, hereinafter, the horizontal direction on the plane is defined as a first direction X, the vertical direction on the plane is defined as a second direction Y, and a normal direction of the plane defined by first direction X and second direction Y, for example, a thickness direction of the display device 100, may be defined as a third direction Z.

Referring to FIG. 3, the pixel PX may include a plurality of sub pixels RSP, GSP, and BSP representing different colors. For example, the pixel PX may include a first sub pixel RSP implementing red, a second sub pixel GSP implementing green, and a third sub pixel BSP implementing blue. Depending on the example embodiment, the first sub pixel RSP may be referred to as a red sub pixel, the second sub pixel GSP as a green sub pixel, and the third sub pixel BSP as a blue sub pixel. A pixel circuit may be disposed in each of the plurality of sub pixels RSP, GSP, and BSP included in the pixel PX.

Each of the plurality of sub pixels RSP, GSP, and BSP may include a first optical area RWE, GWE, and BWE and a second optical area RNE, GNE, and BNE providing different viewing angles.

The first optical area RWE, GWE, and BWE of each of the sub pixels RSP, GSP, and BSP may operate independently of the second optical area RNE, GNE, and BNE of the corresponding sub pixel. For example, each of the sub pixels RSP, GSP, and BSP may include a first light emitting diode ED1 disposed in the first optical area RWE, GWE, and BWE of the corresponding sub pixel, and a second light emitting diode ED2 disposed in the second optical area RNE, GNE, and BNE of the corresponding sub pixel.

In one pixel PX, the first light emitting diode ED1 and the second light emitting diode ED2 may be respectively disposed in the first optical area RWE, GWE, and BWE and the second optical area RNE, GNE, and BNE of the plurality of sub pixels RSP, GSP, and BSP.

For example, one pixel PX may include the first light emitting diode ED1 disposed in the first optical area RWE of the first sub pixel RSP, the second light emitting diode ED2 disposed in the second optical area RNE of the first sub pixel RSP, the first light emitting diode ED1 disposed in the first optical area GWE of the second sub pixel GSP, the second light emitting diode ED2 disposed in the second optical area GNE of the second sub pixel GSP, the first light emitting diode ED1 disposed in the first optical area BWE of the third sub pixel BSP, and the second light emitting diode ED2 disposed in the second optical area BNE of the third sub pixel BSP.

Referring to FIG. 3, at least one first optical member 161 may be disposed in the first optical areas RWE, GWE, and BWE of each of sub pixels RSP, GSP, and BSP so as to overlap first emission areas RE1, GE1, and BE1 of the first light emitting diode ED1. At least one second optical member 162 may be disposed in the second optical areas RNE, GNE, and BNE of each of sub pixels RSP, GSP, and BSP so as to overlap second emission areas RE2, GE2, and BE2 of the second light emitting diode ED2. In this case, the first optical area RWE, GWE, and BWE may have a first viewing angle, and the second optical area RNE, GNE, and BNE may have a second viewing angle smaller than the first viewing angle.

Referring to FIGS. 4 and 5 together, the display device 100 according to an example embodiment of the present disclosure may include a substrate 110, a buffer layer 111, a gate insulating layer 112, an interlayer insulating layer 113, a passivation layer 114, a planarization layer 115, a bank 116, a capping layer 117, a first transistor T1, a second transistor T2, a first light emitting diode ED1, a second light emitting diode ED2, an encapsulation member 180, a touch buffer layer 191, a touch bridge electrode 192, a first touch insulating layer 193, a black matrix 194, a second touch insulating layer 195, a touch electrode 196, a third touch insulating layer 197, a first optical member 161, a second optical member 162, and an optical member protective film 170.

The substrate 110 may include an insulating material. The substrate 110 may include a transparent material. For example, the substrate 110 may include glass or plastic.

The buffer layer 111 may be disposed on the substrate 110. The buffer layer 111 may include an insulating material. For example, the buffer layer 111 may include inorganic insulating materials such as silicon oxide (SiOx) and silicon nitride (SiNx). The buffer layer 111 may have a multilayer structure. For example, the buffer layer 111 may have a laminated structure of a layer made of silicon nitride (SiNx) and a layer made of silicon oxide (SiOx).

The buffer layer 111 may be located between the substrate 110 and the driving portions of sub pixels RSP, GSP, and BSP. The buffer layer 111 may suppress contamination caused by the substrate 110 in the process of forming the driving portions. For example, an upper surface of substrate 110 toward the driving portions of each of sub pixels RSP, GSP, and BSP may be covered by the buffer layer 111. The driving portions of each of sub pixels RSP, GSP, and BSP may be located on the buffer layer 111.

The gate insulating layer 112 may be disposed on the buffer layer 111. The gate insulating layer 112 may include an insulating material. For example, the gate insulating layer 112 may include inorganic insulating materials such as silicon oxide (SiOx) and silicon nitride (SiNx). The gate insulating layer 112 may include a material having a high dielectric constant. For example, the gate insulating layer 112 may include a high-k material such as hafnium oxide (HfO). The gate insulating layer 112 may have a multilayer structure.

The gate insulating layer 112 may extend between semiconductor layers 121 and 221 of transistors T1 and T2 and gate electrodes 122 and 223. For example, the gate electrodes 122 and 223 of the first transistor T1 and the second transistor T2 may be insulated from the semiconductor layers 121 and 221 of the first transistor T1 and the second transistor T2 by the gate insulating layer 112. The gate insulating layer 112 may cover semiconductor layers 121 and 221 of each of the sub pixels RSP, GSP, and BSP. The gate electrodes 122 and 223 of the first transistor T1 and the second transistor T2 may be located on the gate insulating layer 112.

The interlayer insulating layer 113 may be disposed on the gate insulating layer 112. The interlayer insulating layer 113 may include an insulating material. For example, the interlayer insulating layer 113 may include inorganic insulating materials such as silicon oxide (SiOx) and silicon nitride (SiNx). The interlayer insulating layer 113 may extend between gate electrodes 122 and 223 and source electrodes 123 and 225, and between gate electrodes 122 and 223 and drain electrodes 124 and 227 of the transistors T1 and T2, respectively. For example, the source electrodes 123 and 225 and the drain electrodes 124 and 227 of each of the first transistor T1 and the second transistor T2 may be insulated from the gate electrodes 122 and 223 by the interlayer insulating layer 113. The interlayer insulating layer 113 may cover the gate electrodes 122 and 223 of each of the first transistor T1 and the second transistor T2. The source electrodes 123 and 225 and the drain electrodes 124 and 227 of each of the sub pixels RSP, GSP, and BSP may be located on the interlayer insulating layer 113. The gate insulating layer 112 and the interlayer insulating layer 113 may expose source regions and drain regions of the respective semiconductor layers 121 and 221 located in each of the sub pixels RSP, GSP, and BSP.

The passivation layer 114 may be disposed on the interlayer insulating layer 113. The passivation layer 114 may include an insulating material. For example, the passivation layer 114 may include inorganic insulating materials such as silicon oxide (SiOx) and silicon nitride (SiNx).

The passivation layer 114 may suppress damage of the driving portions caused by external moisture and impact. The passivation layer 114 may extend along the surface of the first transistor T1 and the second transistor T2. The passivation layer 114 may contact the interlayer insulating layer 113 outside the driving portions located in each of the sub pixels RSP, GSP, and BSP.

The planarization layer 115 may be disposed on the passivation layer 114. The planarization layer 115 may include an insulating material. The planarization layer 115 may include a material different from that of the passivation layer 114. For example, the planarization layer 115 may include an organic insulating material.

The planarization layer 115 may remove steps by the driving portions of each of the sub pixels RSP, GSP, and BSP. For example, a top surface of the planarization layer 115 opposite to the substrate 110 may be a flat surface.

Meanwhile, the planarization layer 115 may include a groove G. For example, the groove G may be disposed to correspond to the first emission area RE1, GE1, and BE1 of the first light emitting diode ED1. The groove G may be disposed so as to overlap the center of the first light emitting diode ED1 and may change the shape of the first emission layer 142 of the first light emitting diode ED1 to correspond to the groove G. Accordingly, by varying the emission angle of light emitted from the first emission layer 142, luminance deviation according to the viewing angle may be improved.

For example, a vertical cross-sectional shape of the groove G may be formed as an inverse taper shape. Accordingly, the first emission layer 142 of the first light emitting diode ED1 disposed on the planarization layer 115 may have a step. For example, the first emission layer 142 may include a flat portion 142-1a and an inclined portion 142-1b having a different emission angle from the flat portion 142-1a. Accordingly, by adjusting the emission angle of light emitted from the first emission layer 142, the optical path may be controlled. A more detailed description thereof will be given later with reference to the first light emitting diode ED1.

An inclination angle of the groove G may be determined in consideration of the emission angle of light emitted from the first light emitting diode ED1. The inclination angle of the groove G means an angle between a side wall of the groove and an extending plane of a bottom surface of the groove. For example, the inclination angle of the groove G may be 20° to 50°, but is not limited thereto.

On the other hand, the groove G may not be disposed in the second emission area RE2, GE2, and BE2 in which the second light emitting diode ED2 is disposed. For example, the groove G may be disposed in the first emission area RE1, GE1, and BE1 to compensate for luminance deviation according to the viewing angle, so that the first emission area RE1, GE1, and BE1 may more effectively implement a wide viewing mode.

However, the present disclosure is not limited thereto, and the groove G may also be disposed in the second emission area RE2, GE2, and BE2 in which the second light emitting diode ED2 is disposed, as needed.

The first transistor T1 and the second transistor T2 may be disposed on the substrate 110. The first transistor T1 may be electrically connected between a drain electrode of a driving transistor and a first lower electrode 141 of the first light emitting diode ED1. The second transistor T2 may be electrically connected between a drain electrode of the driving transistor and a second lower electrode 151 of the second light emitting diode ED2.

The first transistor T1 may include the first semiconductor layer 121, the first gate electrode 122, the first source electrode 123, and the first drain electrode 124. The first transistor T1 may have the same structure as a switching transistor and a driving transistor.

For example, the first semiconductor layer 121 may be located between the buffer layer 111 and the gate insulating layer 112, the first gate electrode 122 may be located between the gate insulating layer 112 and the interlayer insulating layer 113. The first source electrode 123 and the first drain electrode 124 may be located between the interlayer insulating layer 113 and the passivation layer 114. The first gate electrode 122 may overlap a channel region of the first semiconductor layer 121. The first source electrode 123 may be electrically connected to a source region of the first semiconductor layer 121. The first drain electrode 124 may be electrically connected to a drain region of the first semiconductor layer 121.

The second transistor T2 may include the second semiconductor layer 221, the second gate electrode 223, the second source electrode 225, and the second drain electrode 227. For example, the second semiconductor layer 221 may be located in the same layer as the first semiconductor layer 121, the second gate electrode 223 may be located in the same layer as the first gate electrode 122, and the second source electrode 225 and the second drain electrode 227 may be located in the same layer as the first source electrode 123 and the first drain electrode 124.

The first light emitting diode ED1 and the second light emitting diode ED2 of each of the sub pixels RSP, GSP, and BSP may be disposed on the planarization layer 115 of the corresponding sub pixel.

The first light emitting diode ED1 may emit light representing a specific color. For example, the first light emitting diode ED1 may include the first lower electrode 141, the first emission layer 142, and the first upper electrode 143 sequentially stacked on substrate 110.

The first lower electrode 141 may include a conductive material. The first lower electrode 141 may include a material having a high reflectance. For example, the first lower electrode 141 may include a metal such as aluminum (Al) and silver (Ag). The first lower electrode 141 may have a multilayer structure. For example, the first lower electrode 141 may have a structure in which a reflective electrode made of metal is located between transparent electrodes made of transparent conductive materials such as indium tin oxide (ITO) and indium zinc oxide (IZO). The first lower electrode 141 may be electrically connected to the first drain electrode 124 of the first transistor T1 through a contact hole penetrating the passivation layer 114 and the planarization layer 115.

The first emission layer 142 may generate light of a luminance corresponding to a voltage difference between the first lower electrode 141 and the first upper electrode 143. For example, the first emission layer 142 may include an emission material layer (EML) including an emission material. The emission material may include an organic material, an inorganic material, or a hybrid material.

The first emission layer 142 may have a multilayer structure. For example, the first emission layer 142 may further include at least one of a hole injection layer (HIL), a hole transport layer (HTL), an electron transport layer (ETL), and an electron injection layer (EIL).

Meanwhile, the first emission layer 142 of the first light emitting diode ED1 may include a first portion 142-1 and a second portion 142-2 having different thicknesses, i.e., widths in a third direction Z. Specifically, the first portion 142-1 may be a portion disposed at the center of the first emission layer 142 and may have a relatively small thickness. The second portion 142-2 may be a portion disposed at an end or an edge of the first emission layer 142 and may have a relatively large thickness.

Specifically, the second portion 142-2 disposed at the edge of the first emission layer 142 may be more easily exposed to out-gassing components of the planarization layer 115 than the first portion 142-1, thereby being degraded and contracted. Accordingly, in order to minimize the influence of contraction of the second portion 142-2, the thickness t2 of the second portion 142-2 may be formed thicker than the thickness t1 of the first portion 142-1. Specifically, by forming the second portion 142-2 sufficiently thick, even if the second portion 142-2 is partially degraded, a non-degraded portion may remain. That is, even if the second portion 142-2 is partially degraded and contracted, the remaining non-degraded and non-contracted second portion 142-2 may remain, thereby minimizing the influence of contraction. Thus, reduction of the first emission areas RE1, GE1, and BE1 may also be minimized.

Accordingly, the second portion 142-2 may have a minimum width so that a non-degraded portion may remain even when exposed to out-gassing components, and so that the out-gassing components may not propagate to the first portion 142-1. For example, the width of the second portion 142-2 in a first direction X and/or the second direction Y may be in a range of 1 μm to 3 μm, but is not limited thereto, and may be variously designed depending on the size of the first light emitting diode ED1.

Meanwhile, since the first portion 142-1 of the first light emitting layer 142 corresponds to the center of the first light emitting diode ED1, the first portion 142-1 may be disposed to overlap the groove G of the planarization layer 115 disposed corresponding to the center of the first light emitting diode ED1. Accordingly, the first portion 142-1 may be disposed concavely along the shape of the groove G.

Specifically, since the groove G has an inverse taper shape, the first portion 142-1 may have a step. For example, the first portion 142-1 may include a flat portion 142-1a and an inclined portion 142-1b enclosing the flat portion 142-1a. For example, the angle of the inclined portion 142-1 b may be in a range of 20° to 50°, the same as the inclination angle of the groove G. The angle of the inclined portion 142-1b means an angle between the inclined portion 142-1b and an extending plane of the flat portion 142-1a. Accordingly, light emitted from the inclined portion 142-1b may be directed laterally by the flat portion 142-1a.

In particular, the inclined portion 142-1b may be disposed more adjacent to the second portion 142-2 than the flat portion 142-1a. Accordingly, light from the inclined portion 142-1b may be emitted in a direction similar to the emission direction of the second portion 142-2. Thus, luminance deviation according to the viewing angle due to degradation of the second portion 142-2 may be minimized.

Meanwhile, a height difference between the second portion 142-2 and the first portion 142-1 of the first emission layer 142 may be determined in consideration of the emission angle of light emitted from the first light emitting diode ED1. For example, the difference between the height of the top end of the second portion 142-2 and the height of the top end of the first portion 142-1 (i.e., the height of the top end of the first portion located at the lowest position) may be in a range of 0.5 μm to 1.5 μm, but is not limited thereto.

On the other hand, the second portion 142-2 of the first emission layer 142 may not overlap the groove G. In other words, the portion of the first emission layer 142 that does not overlap the groove G may be thicker than the portion overlapping the groove G, but is not limited thereto.

That is, according to an example embodiment of the present disclosure, by designing the thickness of the first emission layer 142 of the first light emitting diode ED1 disposed in the first emission area RE1, GE1, and BE1 differently according to each area, reduction of the first emission area RE1, GE1, and BE1 that implements a wide field of view mode may be minimized, so that the wide field of view mode may be implemented more effectively.

The first upper electrode 143 may include a conductive material. The first upper electrode 143 may include a material different from that of the first lower electrode 141. A transmittance of the first upper electrode 143 may be higher than that of the first lower electrode 141. For example, the first upper electrode 143 may be a transparent electrode made of a transparent conductive material such as indium tin oxide (ITO) or indium zinc oxide (IZO). Accordingly, in the display device 100 according to an example embodiment of the present disclosure, light generated by the first emission layer 142 may be emitted through the first upper electrode 143.

The second light emitting diode ED2 may include, like the first light emitting diode ED1, the second lower electrode 151, the second emission layer 152, and the second upper electrode 153 sequentially stacked on the substrate 110.

The second lower electrode 151 may correspond to the first lower electrode 141, the second emission layer 152 may correspond to the first emission layer 142, and the second upper electrode 153 may correspond to the first upper electrode 143. For example, the second lower electrode 151 may be formed with the same structure as the first lower electrode 141 for the first light emitting diode ED1, and the same applies to the second emission layer 152 and the second upper electrode 153. For example, the first light emitting diode ED1 and the second light emitting diode ED2 may be formed to have the same structure. However, the present disclosure is not limited thereto, and in some cases, at least some configurations of the first light emitting diode ED1 and the second light emitting diode ED2 may be formed differently.

In an example embodiment, the second emission layer 152 may be spaced apart from the first emission layer 142. Accordingly, in the display device according to an example embodiment of the present disclosure, light emission caused by leakage current may be suppressed.

Meanwhile, the second emission layer 152 of the second light emitting diode ED2 may have a uniform thickness unlike the first emission layer 142 of the first light emitting diode ED1. That is, a portion corresponding to the central area and a portion corresponding to the edge area of the second emission layer 152 may have the same thickness, but are not limited thereto.

However, the present disclosure is not limited thereto, and the second emission layer 152 of the second light emitting diode ED2 may also be designed to have different thicknesses by areas.

According to an example embodiment of the present disclosure, in the display device, light may be generated only from either the first emission layer 142 or the second emission layer 152 depending on a user's selection or predetermined conditions.

The second lower electrode 151 of each of the sub pixels RSP, GSP, and BSP may be spaced apart from the first lower electrode 141 of the corresponding sub pixel. For example, a bank 116 may be disposed between the first lower electrode 141 and the second lower electrode 151 of each of the sub pixels RSP, GSP, and BSP. The bank 116 may include an insulating material. For example, the bank 116 may include an organic insulating material. The bank 116 may include a material different from that of the planarization layer 115.

The second lower electrode 151 of each of the sub pixels RSP, GSP, and BSP may be insulated from the first lower electrode 141 of the corresponding sub pixel by the bank 116. For example, the bank 116 may cover edge portions of the first lower electrode 141 and the second lower electrode 151 located in each of the sub pixels RSP, GSP, and BSP. The bank 116 may define the first emission area RE1, GE1, and BE1 of the first light emitting diode ED1 and the second emission area RE2, GE2, and BE2 of the second light emitting diode ED2. For example, the first emission area RE1, GE1, and BE1 of the first light emitting diode ED1 may be defined as a region surrounded by an edge area of the first lower electrode 141 covered by the bank 116. The second emission area RE2, GE2, and BE2 of the second light emitting diode ED2 may be defined as a region surrounded an edge area of the second lower electrode 151 covered by the bank 116.

Referring to FIG. 3, the size of first emission area RE1, GE1, and BE1 of the first light emitting diode ED1 defined in each of the sub pixels RSP, GSP, and BSP may be larger than the size of the second emission area RE2, GE2, and BE2 of the second light emitting diode ED2, but is not limited thereto. The first emission layer 142 and the first upper electrode 143 of the first light emitting diode ED1 located in each of the sub pixels RSP, GSP, and BSP may be laminated on a partial area of the first lower electrode 141 exposed by the bank 116. Specifically, the first emission layer 142 and the first upper electrode 143 may be laminated on a partial area of the first lower electrode 141 exposed by the bank 116 and on the bank 116. The second emission layer 152 and the second upper electrode 153 of the second light emitting diode ED2 located in each of the sub pixels RSP, GSP, and BSP may be laminated on a partial area of the second lower electrode 151 exposed by the bank 116. Specifically, the second emission layer 152 and the second upper electrode 153 may be laminated on a partial area of the second lower electrode 151 exposed by the bank 116 and on the bank 116. The second upper electrode 153 of each of the sub pixels RSP, GSP, and BSP may be electrically connected to the first upper electrode 143 of the corresponding sub pixel. For example, a voltage applied to the second upper electrode 153 of the second light emitting diode ED2 located in each of the sub pixels RSP, GSP, and BSP may be the same as a voltage applied to the first upper electrode 143 of the first light emitting diode ED1 located in the corresponding sub pixel. The second upper electrode 153 of each of the sub pixels RSP, GSP, and BSP may include the same material as the first upper electrode 143 of the corresponding sub pixel. For example, the second upper electrode 153 of each of the sub pixels RSP, GSP, and BSP may be formed simultaneously with the first upper electrode 143 of the corresponding sub pixel. The second upper electrode 153 of each of the sub pixels RSP, GSP, and BSP may extend onto the bank 116 to directly contact the first upper electrode 143 of the corresponding sub pixel. The luminance of the first optical area RWE, GWE, and BWE and the luminance of the second optical area RNE, GNE, and BNE located in each of the sub pixels RSP, GSP, and BSP may be controlled by a driving current generated in the corresponding sub pixel.

A capping layer 117 may be disposed on the first light emitting diode ED1 and the second light emitting diode ED2 of each of the sub pixels RSP, GSP, and BSP. The capping layer 117 may suppress damage of light emitting diodes ED1 and ED2 caused by external moisture and impact. The capping layer 117 may be formed of, for example, an inorganic insulating material such as silicon oxide (SiOx) or silicon nitride (SiNx), but is not limited thereto and may also be formed of an organic insulating material.

An encapsulation member 180 may be disposed on the capping layer 117. The encapsulation member 180 may suppress damage of light emitting diodes ED1 and ED2 caused by external moisture and impact. The encapsulation member 180 may have a multilayer structure. For example, the encapsulation member 180 may include a first encapsulation layer 181, a second encapsulation layer 182, and a third encapsulation layer 183 sequentially laminated, but is not limited thereto.

The first encapsulation layer 181, the second encapsulation layer 182, and the third encapsulation layer 183 may include an insulating material. The second encapsulation layer 182 may include a material different from those of the first encapsulation layer 181 and the third encapsulation layer 183. For example, the first encapsulation layer 181 and the third encapsulation layer 183 may be inorganic encapsulation layers including inorganic insulating materials, and the second encapsulation layer 182 may be an organic encapsulation layer including an organic insulating material. Accordingly, in display device 100, the light emitting diodes ED1 and ED2 may be more effectively suppressed from damage caused by external moisture and impact.

A touch buffer layer 191 may be disposed on the encapsulation member 180. The touch buffer layer 191 may be disposed between the encapsulation member 180 and the touch bridge electrode 192 so as to insulate the touch bridge electrode 192. For example, the touch buffer layer 191 may include an insulating material. For example, the touch buffer layer 191 may be formed of an organic insulating material or an inorganic insulating material, but is not limited thereto.

The touch bridge electrode 192 may be disposed on the touch buffer layer 191. The touch bridge electrode 192 may be disposed in the second optical area RNE, GNE, and BNE located in each of the sub pixels RSP, GSP, and BSP. For example, the touch bridge electrode 192 may be disposed in the second emission area RE2, GE2, and BE2 of the second optical area RNE, GNE, and BNE.

For example, the touch bridge electrode 192 may include a metal material such as titanium (Ti), aluminum (Al), silver (Ag), copper (Cu), or a magnesium-silver alloy (Mg: Ag), but is not limited thereto.

The first touch insulating layer 193 may be disposed on the touch bridge electrode 192. The first touch insulating layer 193 may be disposed between the touch bridge electrode 192 and a black matrix 194 so as to insulate the touch bridge electrode 192.

The first touch insulating layer 193 may include an insulating material. For example, the first touch insulating layer 193 may include an organic insulating material or an inorganic insulating material, but is not limited thereto.

The black matrix 194 may be disposed on the first touch insulating layer 193. The black matrix 194 may be disposed between a plurality of sub pixels RSP, GSP, and BSP to reduce color mixing of the plurality of sub pixels RSP, GSP, and BSP. Accordingly, the black matrix 194 may be disposed so as to overlap the bank 116.

The second touch insulating layer 195 may be disposed on the black matrix 194. The second touch insulating layer 195 may be disposed between the black matrix 194 and the touch electrode 196 so as to insulate the touch electrode 196.

The second touch insulating layer 195 may include an insulating material. For example, the second touch insulating layer 195 may include an organic insulating material or an inorganic insulating material, but is not limited thereto.

A plurality of touch electrodes 196 may be disposed on the second touch insulating layer 195. The plurality of touch electrodes 196 may be configured to sense an external touch input using a user's finger or a touch pen. The touch electrode 196 may include, for example, a metal material such as titanium (Ti), aluminum (Al), silver (Ag), copper (Cu), or a magnesium-silver alloy (Mg: Ag), but is not limited thereto.

A third touch insulating layer 197 may be disposed on the touch electrodes 196. The third touch insulating layer 197 may be disposed between the touch electrodes 196 and the optical members 161 and 162 so as to insulate the touch electrodes 196.

The third touch insulating layer 197 may include an insulating material. For example, the third touch insulating layer 197 may include an organic insulating material or an inorganic insulating material, but is not limited thereto.

Referring to FIGS. 4 and 5, the first optical member 161 and the second optical member 162 may be disposed on the third touch insulating layer 197.

For example, the first optical member 161 and the second optical member 162 may each be disposed so as to cover edges of the plurality of touch electrodes 196, but are not limited thereto and may also be disposed so as not to overlap the plurality of touch electrodes 196.

The first optical member 161 may be disposed on the first light emitting diode ED1, and for example, may have a semi-cylindrical shape. Light generated by the first light emitting diode ED1 of each of the sub pixels RSP, GSP, and BSP may be emitted through the first optical member 161 disposed in the first optical area RWE, GWE, and BWE of the corresponding sub pixel.

The first optical member 161 may have a shape in which light in at least one direction is not restricted. For example, a planar shape of the first optical member 161 located in each of the sub pixels RSP, GSP, and BSP may have a bar shape extending in the first direction X.

In such a case, a traveling direction of the light emitted from the first optical area RWE, GWE, and BWE of each of the sub pixels RSP, GSP, and BSP may not be restricted in the first direction X. For example, content (or an image) provided through the first optical area RWE, GWE, and BWE of each of the sub pixels RSP, GSP, and BSP may be shared with people adjacent to the user in the first direction X. Accordingly, the content provided by light emitted through the first optical member 161 may be provided within first viewing angle range, which is wider than the viewing angle range of the content provided by light emitted through the second optical member 162. For example, the content provided by light emitted through the first optical member 161 may be provided in a wide field of view mode (share mode).

The second optical member 162 may be disposed on the second light emitting diode ED2, and for example, may have a hemispherical shape. Light generated by the second light emitting diode ED2 of each of the sub pixels RSP, GSP, and BSP may be emitted through the second optical member 162 disposed in the second optical area RNE, GNE, and BNE of the corresponding sub pixel. The second optical member 162 may restrict a traveling direction of transmitted light in the first direction X and/or second direction Y. For example, a planar shape of the second optical member 162 located in each of the sub pixels RSP, GSP, and BSP may be a circular shape. However, the present disclosure is not limited thereto, and the planar shape of the second optical member 162 located in each of the sub pixels RSP, GSP, and BSP may also be a polygonal shape.

In such a case, the traveling direction of light emitted from the second optical area RNE, GNE, and BNE of each of the sub pixels RSP, GSP, and BSP may be restricted in the first direction X and/or the second direction Y. For example, content (or an image) provided through the second optical area RNE, GNE, and BNE of each of the sub pixels RSP, GSP, and BSP may not be shared with people around the user. Accordingly, the content provided by light emitted through the second optical member 162 may be provided within the second viewing angle range, which is narrower than the viewing angle range of the content provided through the first optical member 161. For example, the content provided by light emitted through the second optical member 162 may be provided in a narrow field of view mode (private mode).

The first emission area RE1, GE1, and BE1 of each of sub pixels RSP, GSP, and BSP may have a shape corresponding to the first optical member 161 of the corresponding sub pixel. For example, a planar shape of the first emission area RE1, GE1, and BE1 of each of the sub pixels RSP, GSP, and BSP may have a bar shape extending in the first direction X. The first optical member 161 of each of the sub pixels RSP, GSP, and BSP may have a size larger than the first emission area RE1, GE1, and BE1 of the corresponding sub pixel. Accordingly, efficiency of light emitted from the first emission area RE1, GE1, and BE1 of each of the sub pixels RSP, GSP, and BSP may be improved.

The second emission area RE2, GE2, and BE2 of each of the sub pixels RSP, GSP, and BSP may have a shape corresponding to the second optical member 162 of the corresponding sub pixel. For example, a planar shape of the second emission area RE2, GE2, and BE2 of each of the sub pixels RSP, GSP, and BSP may be a circular shape or a polygonal shape. The second optical member 162 of each of the sub pixels RSP, GSP, and BSP may have a size larger than the second emission area RE2, GE2, and BE2 of the corresponding sub pixel. Accordingly, efficiency of light emitted from the second emission area RE2, GE2, and BE2 of each of the sub pixels RSP, GSP, and BSP may be improved.

Depending on the example embodiment, the first optical area RWE, GWE, and BWE of one sub pixel RSP, GSP, and BSP may include one first emission area RE1, GE1, and BE1. In addition, the second optical area RNE, GNE, and BNE of one sub pixel RSP, GSP, and BSP may include a plurality of second emission areas RE2, GE2, and BE2.

Depending on the example embodiment, one first optical member 161 may be disposed on the first optical area RWE, GWE, and BWE of one sub pixel RSP, GSP, and BSP. In addition, a plurality of second optical members 162 may be disposed on the second optical area RNE, GNE, and BNE of one sub pixel RSP, GSP, and BSP.

Referring to FIG. 3, the number of second emission areas RE2, GE2, and BE2 may be different for each of the sub pixels RSP, GSP, and BSP. For example, each of the number of second emission areas GE2 defined in the second optical area GNE of the second sub pixel GSP and the number of second emission areas BE2 defined in the second optical area BNE of the third sub pixel BSP may be larger than the number of second emission areas RE2 defined in the second optical area RNE of the first sub pixel RSP. In such a case, efficiency deviation of each second light emitting diode ED2 disposed on the second optical area RNE, GNE, and BNE may be compensated by the number of second emission areas RE2, GE2, and BE2 defined in the second optical area RNE, GNE, and BNE of each of the sub pixels RSP, GSP, and BSP.

An optical member protective film 170 may be disposed on the first optical member 161 and the second optical member 162 of each of the sub pixels RSP, GSP, and BSP. The optical member protective film 170 may include an insulating material. For example, the optical member protective film 170 may include an organic insulating material. A refractive index of the optical member protective film 170 may be smaller than refractive indices of the first optical member 161 and the second optical member 162 located in each of the sub pixels RSP, GSP, and BSP. Accordingly, in the display device 100 according to an example embodiment of the present disclosure, light passing through the first optical member 161 and the second optical member 162 of each of the sub pixels RSP, GSP, and BSP may not be reflected toward the substrate 110 due to the difference in refractive indices from the optical member protective film 170.

A portion disposed at an end of an emission layer of a light emitting diode may be relatively easily exposed to out-gassing components compared to a portion disposed at the center, and thus may be relatively easily degraded. When the emission layer is degraded in this way, the emission layer may contract, and accordingly, the emission area may be reduced.

Meanwhile, in the display device, light emitting diodes may be selectively driven according to a user's selection or predetermined conditions. Accordingly, some of the light emitting diodes may be continuously driven, while others may be driven for a relatively shorter time. In this case, some of the continuously driven light emitting diodes generate a large amount of heat, so that they may be relatively easily degraded. As such, when the degree of degradation is different for each light emitting diode, a deviation in the degree of contraction of the light emitting diode may occur. In other words, a deviation may occur in the size of the emission areas between the light emitting diodes, which may lead to luminance deviation among areas.

Accordingly, in the display device 100 according to an example embodiment of the present disclosure, a thickness t2 of the second portion 142-2 disposed at an end of the first emission layer 142 of the first light emitting diode ED1 may be formed to be thicker than a thickness t1 of the first portion 142-1 disposed at the center. Thus, even if the second portion 142-2 is partially degraded due to exposure to out-gassing components, a remaining non-degraded portion may remain. Therefore, the influence of contraction due to degradation of the first emission layer 142 may be minimized, and consequently reduction of the first emission areas RE1, GE1, and BE1 may be minimized. Therefore, even if differences occur in the degree of degradation of the first light emitting diode ED1, deviations in size among the first emission areas RE1, GE1, and BE1 may be minimized. As a result, luminance deviation according to the viewing angle among the first light emitting diodes ED1 may be minimized.

In addition, in the display device 100 according to an example embodiment of the present disclosure, the planarization layer 115 may include the groove G disposed to overlap the first light emitting diode ED1. Accordingly, the first emission layer 142 of the first light emitting diode ED1 may be disposed along the shape of the groove G. For example, when the groove G has an inverse taper shape (for example, an inverted trapezoidal shape), the first emission layer 142 may have a step. For example, the first emission layer 142 may include a flat portion 142-1a as well as an inclined portion 142-1b. In this case, light emitted from the flat portion 142-1a and the inclined portion 142-1b may be emitted with different emission angles. That is, in the display device 100 according to an example embodiment of the present disclosure, by forming the groove G overlapping the first light emitting diode ED1 in the planarization layer 115, emission angles of light emitted from the first emission layer 142 may be adjusted in various ways to control the optical path. Thus, even if degradation occurs in the first light emitting diode ED1, luminance deviation according to the viewing angle may be improved by controlling the optical path. Accordingly, by implementing uniform luminance, the display quality of the display device 100 may be improved.

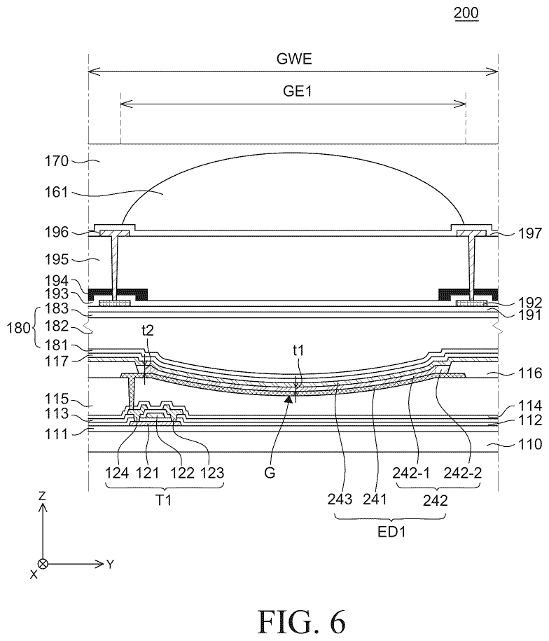

FIG. 6 is a cross-sectional view of a pixel of the display device according to another example embodiment of the present disclosure. A display device 200 of FIG. 6 is substantially the same as the display device 100 of FIGS. 1 to 5 except that only the shape of the groove G and the first light emitting diode ED1 are different, and therefore, redundant description will be omitted.

The first light emitting diode ED1 may include a first lower electrode 241, a first emission layer 242, and a first upper electrode 243 sequentially stacked on substrate 110.

Referring to FIG. 6, the planarization layer 115 may include the groove G. For example, the groove G may be disposed to correspond to the first emission area RE1, GE1, and BE1 of the first light emitting diode ED1. The groove G may be disposed to overlap the center of the first light emitting diode ED1 and may change the shape of the first emission layer 242 of the first light emitting diode ED1 to correspond to the groove G. Accordingly, by varying the emission angle of light emitted from the first emission layer 242, luminance deviation according to the viewing angle may be improved.

For example, a vertical cross-sectional shape of the groove G may be formed as a curved surface. Accordingly, a vertical cross section of the first emission layer 242 of the first light emitting diode ED1 disposed on the planarization layer 115 may also be formed as a curved surface. Thus, compared with the case where the first emission layer is disposed flat, the width of the first emission layer 242 may be relatively increased. In addition, since the first emission layer 242 has an inclination, the emission angles of light emitted from the first emission layer 242 may be diversified.

Meanwhile, the first emission layer 242 of the first light emitting diode ED1 may include a first portion 242-1 and a second portion 242-2 having different thicknesses, i.e., widths in the third direction Z. Specifically, the first portion 242-1 may be a portion disposed at the center of the first emission layer 242 and may have a relatively small thickness. The second portion 242-2 may be a portion disposed at an end or edge of the first emission layer 242 and may have a relatively large thickness.

Specifically, the second portion 242-2 disposed at the edge of the first emission layer 242 may be more easily exposed to out-gassing components of the planarization layer 115 than the first portion 242-1, thereby being degraded and contracted. Accordingly, in order to minimize the influence of contraction of the second portion 242-2, the thickness t2 of the second portion 242-2 may be formed thicker than the thickness t1 of the first portion 242-1. Specifically, by forming the second portion 242-2 sufficiently thick, even if the second portion 242-2 is partially degraded, a non-degraded portion may be secured. That is, even if the second portion 242-2 is partially degraded and contracted, the remaining non-degraded and non-contracted second portion 242-2 may remain, thereby minimizing the influence of contraction. Thus, reduction of the first emission areas RE1, GE1, and BE1 may also be minimized.

Accordingly, the second portion 242-2 may have a minimum width so that a non-degraded portion may remain even when exposed to out-gassing components, and so that the out-gassing components may not propagate to the first portion 242-1. For example, the width of the second portion 242-2 in the first direction X and/or the second direction Y may be in a range of 1 μm to 3 μm, but is not limited thereto, and may be variously designed depending on the size of the first light emitting diode ED1.

Meanwhile, since the first portion 242-1 corresponds to the center of the first light emitting diode ED1, the first portion 242-1 may be disposed to overlap the groove G of the planarization layer 115 disposed corresponding to the center of the first light emitting diode ED1. Accordingly, the first portion 242-1 may be disposed concavely along the shape of groove G.

For example, since the groove G has a curved vertical cross-sectional shape, a vertical cross-sectional shape of the first portion 242-1 may also be a curved surface. A vertical cross-sectional shape of the second portion 242-2 may be a flat surface. Thus, compared with the case where all portions of the first emission layer are disposed flat, the width of the first emission layer 242 may be relatively increased. In addition, since the first emission layer 242 has an inclination, emission angles of light emitted from the first emission layer 242 may be relatively diversified. That is, by adjusting the emission angle of the first portion 242-1 of the first emission layer 242, the optical path may be controlled.

Meanwhile, a height difference between the second portion 242-2 and the first portion 242-1 of the first emission layer 242 may be determined in consideration of the emission angle of light emitted from the first light emitting diode ED1. For example, the difference between the height of the top end of the second portion 242-2 and the height of the top end of the first portion 242-1 (i.e., the height of the top end of the first portion located at the lowest position) may be in a range of 0.5 μm to 1.5 μm, but is not limited thereto.

On the other hand, the second portion 242-2 of the first emission layer 242 may not overlap the groove G. Accordingly, a top surface of the second portion 242-2 may be formed as a flat surface, unlike the top surface of the first portion 242-1, but is not limited thereto.

In the display device 200 according to another example embodiment of the present disclosure, a thickness t2 of the second portion 242-2 disposed at an end of the first emission layer 242 of the first light emitting diode ED1 may be formed to be thicker than a thickness t1 of the first portion 242-1 disposed at the center. Thus, even if the second portion 242-2 is partially degraded due to exposure to out-gassing components, a remaining non-degraded portion may remain. Therefore, the influence of contraction due to degradation of the first emission layer 242 may be minimized, and consequently reduction of the first emission areas RE1, GE1, and BE1 may be minimized. Therefore, even if differences occur in the degree of degradation of the first light emitting diode ED1, deviations in size among the first emission areas RE1, GE1, and BE1 may be minimized. As a result, luminance deviation according to the viewing angle among the first light emitting diodes ED1 may be minimized.

In addition, in the display device 200 according to another example embodiment of the present disclosure, the planarization layer 115 may include the groove G disposed to overlap the first light emitting diode ED1. Accordingly, the first emission layer 242 of the first light emitting diode ED1 may be disposed along the shape of the groove G. For example, when the groove G has a curved vertical cross-sectional shape, the vertical cross-sectional shape of the first emission layer 242 may also be formed as a curved surface. Thus, compared with the case where the first emission layer is disposed flat, the width of the first emission layer 242 may be relatively increased. In addition, since the first emission layer 242 has an inclination corresponding to the curved surface, emission angles of light emitted from the first emission layer 242 may be diversified. That is, in the display device 200 according to another example embodiment of the present disclosure, by forming the groove G overlapping the first light emitting diode ED1 in the planarization layer 115, emission angles of light emitted from the first emission layer 242 may be adjusted in various ways. In other words, even if degradation occurs in the first light emitting diode ED1, luminance deviation according to the viewing angle may be improved by controlling the optical path. Accordingly, by implementing uniform luminance, the display quality of the display device 200 may be improved.

The example embodiments of the present disclosure can also be described as follows:
According to an aspect of the present disclosure, there is provided a display device. The display device includes a substrate, a planarization layer disposed on the substrate and including a groove, a light emitting diode disposed on the planarization layer, the light emitting diode including a first electrode overlapping the groove, an emission layer disposed on the first electrode, and a second electrode disposed on the emission layer, and an optical member having a bar shape disposed on the light emitting diode. The emission layer includes a first portion disposed at a center and a second portion enclosing the first portion and disposed at an edge, and a thickness of the second portion is greater than a thickness of the first portion.

The groove of the planarization layer may be disposed to correspond to the first portion.

The second portion of the emission layer may not overlap the groove, and the first portion of the emission layer may overlap the groove.

A vertical cross-sectional shape of the groove may be an inverse tapered shape.

The first portion may have a step.

The first portion may include a flat portion and an inclined portion disposed to enclose the flat portion, and an angle of the inclined portion may be in a range of 20° to 50°.

A vertical cross-sectional shape of the groove may be a curved surface.

A vertical cross-sectional shape of the first portion may be a curved surface, and a vertical cross-sectional shape of the second portion may be a flat surface.

A difference between a height of a top end of the second portion and a height of a top end of the first portion may be in a range of 0.5 μm to 1.5 μm.

A width of the second portion may be in a range of 1 μm to 3 μm.

The display device may further include a bank disposed on the planarization layer and defining an emission area and a non-emission area. The groove may be disposed to overlap the emission area.

According to another aspect of the present disclosure, there is provided a display device. The display device includes a substrate, an active area in which a plurality of sub pixels is defined, a non-active area outside the active area, a planarization layer disposed on the substrate, a first light emitting diode and a second light emitting diode disposed in each of the plurality of sub pixels, a first optical member disposed on the first light emitting diode and having a semi-cylindrical shape and a second optical member disposed on the second light emitting diode and having a hemispherical shape. Each of the first light emitting diode and the second light emitting diode includes a first electrode, an emission layer, and a second electrode. The emission layer includes a first portion disposed at a center and a second portion enclosing the first portion and disposed at an edge. A thickness of the second portion of the emission layer of the first light emitting diode is greater than a thickness of the first portion of the emission layer of the first light emitting diode. A thickness of the second portion of the emission layer of the second light emitting diode is the same as a thickness of the first portion of the emission layer of the second light emitting diode.

The planarization layer may include a groove disposed to overlap the first light emitting diode.

The groove may be disposed to overlap only the first light emitting diode among the first light emitting diode and the second light emitting diode.

The groove may be disposed to correspond to the first portion of the emission layer of the first light emitting diode.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a planarization layer disposed on the substrate and including a groove;
a light emitting diode disposed on the planarization layer, the light emitting diode including a first electrode overlapping the groove, an emission layer disposed on the first electrode, and a second electrode disposed on the emission layer; and
an optical member having a bar shape disposed on the light emitting diode,
wherein the emission layer includes a first portion disposed at a center and a second portion enclosing the first portion and disposed at an edge, and a thickness of the second portion is greater than a thickness of the first portion.

2. The display device according to claim 1, wherein the groove of the planarization layer is disposed to correspond to the first portion.

3. The display device according to claim 2, wherein the second portion of the emission layer does not overlap the groove, and the first portion of the emission layer overlaps the groove.

4. The display device according to claim 1, wherein a vertical cross-sectional shape of the groove is an inverse tapered shape.

5. The display device according to claim 4, wherein the first portion has a step.

6. The display device according to claim 4, wherein the first portion includes a flat portion and an inclined portion disposed to enclose the flat portion, and an angle of the inclined portion is in a range of 20° to 50°.

7. The display device according to claim 1, wherein a vertical cross-sectional shape of the groove is a curved surface.

8. The display device according to claim 7, wherein a vertical cross-sectional shape of the first portion is a curved surface, and a vertical cross-sectional shape of the second portion is a flat surface.

9. The display device according to claim 1, wherein a difference between a height of a top end of the second portion and a height of a top end of the first portion is in a range of 0.5 μm to 1.5 μm.

10. The display device according to claim 1, wherein a width of the second portion is in a range of 1 μm to 3 μm.

11. The display device according to claim 1, further comprising:
a bank disposed on the planarization layer and defining an emission area and a non-emission area,
wherein the groove is disposed to overlap the emission area.

12. A display device, comprising:
a substrate;
an active area in which a plurality of sub pixels is defined;
a non-active area outside the active area;
a planarization layer disposed on the substrate;
a first light emitting diode and a second light emitting diode disposed in each of the plurality of sub pixels;
a first optical member disposed on the first light emitting diode and having a semi-cylindrical shape; and
a second optical member disposed on the second light emitting diode and having a hemispherical shape,
wherein each of the first light emitting diode and the second light emitting diode includes a first electrode, an emission layer, and a second electrode,
wherein the emission layer includes a first portion disposed at a center and a second portion enclosing the first portion and disposed at an edge,
wherein a thickness of the second portion of the emission layer of the first light emitting diode is greater than a thickness of the first portion of the emission layer of the first light emitting diode, and
wherein a thickness of the second portion of the emission layer of the second light emitting diode is same as a thickness of the first portion of the emission layer of the second light emitting diode.

13. The display device according to claim 12, wherein the planarization layer includes a groove disposed to overlap the first light emitting diode.

14. The display device according to claim 13, wherein the groove is disposed to overlap only the first light emitting diode among the first light emitting diode and the second light emitting diode.

15. The display device according to claim 14, wherein the groove is disposed to correspond to the first portion of the emission layer of the first light emitting diode.
